(19) United States
(12) Patent Application Publication
(10) Pub. No.: US 2014/0226296 A1
(43) Pub. Date: Aug. 14, 2014

(54) MULTI-LAYER WIRING BOARD AND METHOD FOR PRODUCING MULTI-LAYER WIRING BOARD

(71) Applicant: KABUSHIKI KAISHA TOYOTA , JIDOSHOKKI, Aichi (JP)

(72) Inventors: Hiroaki Asano, Kariya-shi (JP); Yasuhiro Koike, Kariya-shi (JP); Kiminori Ozaki, Kariya-shi (JP); Hitoshi Shimadu, Kariya-shi (JP); Tetsuya Furuta, Kariya-shi (JP); Masao Miyake, Kariya-shi (JP); Takahiro Hayakawa, Ogaki-shi (JP); Tomoaki Asai, Nagoya-shi (JP); Ryou Yamauchi, Hashima-shi (JP)

(73) Assignee: KABUSHIKI KAISHA TOYOTA JIDOSHOKKI, Aichi-ken (JP)

(21) Appl. No.: 14/129,399

(22) PCT Filed: Feb. 10, 2012
(86) PCT No.: PCT/JP2012/053183

§ 371 Date: Apr. 21, 2014

(30) Foreign Application Priority Data
Jul. 6, 2011 (JP) 2011-150266

(51) Int. Cl. H05K 1/02; H05K 1/18

(52) U.S. Cl. CPC H05K 1/0263; H05K 1/18
USPC 361/767

(57) ABSTRACT

This multi-layer wiring board is provided with an insulating substrate, an inner layer copper sheet, and an outer layer copper foil. The inner layer copper sheet is disposed within the insulating substrate and has been patterned. The outer layer copper foil is disposed in a state of having been patterned at the surface of the insulating substrate, is thinner than the inner layer copper sheet, and has a cross-sectional area of the current path that is smaller than the cross-sectional area of the current path of the inner layer copper sheet. As a result, provided are: a multi-layer wiring board that can flow a large current and a smaller current while suppressing an increase in the projected area of the substrate; and a method for producing the multi-layer wiring board.

### TECHNICAL FIELD

The present invention relates to a multi-layer wiring board and a method for manufacturing a multi-layer wiring board.

### BACKGROUND ART

Patent document 1 discloses a printed substrate allowing for the flow of a large current by arranging a plurality of concentrated current through holes that extend through the substrate from a front side to a back side.

### PRIOR ART DOCUMENT

### Patent Document

Patent Document 1: Japanese Laid-Open Patent Publication No. 2010-267649

### SUMMARY OF THE INVENTION

### Problems that are to be Solved by the Invention

In a configuration in which a large current flows through a conductive pattern, for a thin conductive pattern, the cross-sectional area needs to be increased. Thus, the width needs to be increased. This widens the area occupied by the conductive pattern. For a thick conductive pattern, the width may be small. However, the etching time used for patterning is prolonged. This increases costs.

Further, when connecting a substrate including a thin conductive pattern and a substrate including a thick conductive pattern on a substrate having a flush plane, the planar area of the substrate increases.

It is an object of the present invention to provide a multi-layer wiring board and a method for manufacturing the multi-layer wiring board allowing for the flow of a large current and a smaller current while suppressing an increase in the planar area of the substrate.

### Means for Solving the Problem

To achieve the above object, a multi-layer wiring board according to the present invention includes an insulative base material, a patterned inner layer metal plate arranged in the insulative base material, and an outer layer metal foil arranged in a patterned state on a surface of the insulative base material. The outer layer metal foil is thinner than the inner layer metal plate and has a current path with a cross-sectional area smaller than that of a current path of the inner layer metal plate.

In the above configuration, the patterned inner layer metal plate is arranged in the insulative base material, and a large current is allowed to flow to the patterned inner layer metal plate. Further, the patterned outer layer metal foil is arranged on the surface of the insulative base material, and a smaller current than for the inner layer metal plate may flow to the outer layer metal foil.

In a configuration in which a large current flows through the conductive pattern, for a thin conductive pattern, the cross-sectional area needs to be increased. Thus, the width needs to be increased, and a wide area is occupied by the conductive pattern. In contrast, with the present invention, a large current may flow to the patterned inner layer metal plate. Thus, the conductive pattern occupies a small area. Further, a smaller current than for the inner layer metal plate may flow to the patterned outer layer metal foil. Since the outer layer metal foil is arranged on the surface of the insulative base material, the planar area is small.

In this manner, a large current and a smaller current are allowed to flow while suppressing the increase in the planar area of the substrate.

In one aspect of the present invention, the outer layer metal foil is arranged on two surfaces of the insulative base material. In the above configuration, the outer layer metal foil may be arranged on both surfaces of the insulative base material.

In one aspect of the present invention, a conductive pattern formed from the inner layer metal plate is extended out of the insulative base material and fixed to a housing.

In one aspect of the present invention, the insulative base material includes an insulative core substrate, and the patterned inner layer metal plate is adhered to the insulative core substrate.

In one aspect of the present invention, the inner layer metal plate is a copper plate.

In one aspect of the present invention, a six-layer structure includes a pair of first layers, which are formed from the inner layer metal plate and arranged one above the other in a stacking direction, a pair of second layers, which are formed from the outer layer metal foil and are arranged one above the other in the stacking direction, and a pair of third layers, which are arranged one above the other in the stacking direction.

One aspect of the present invention includes a through hole extending in the stacking direction from one of the pair of second layers, arranged one above the other in the stacking direction, to the other second layer.

In one aspect of the present invention, at least one of openings of the through hole is filled with an insulating material, and the third layer is arranged on the insulating material.

In the above configuration, the substrate may be miniaturized.

One aspect of the present invention includes a splitting hole extending in the stacking direction from one of the pair of second layers, arranged one above the other in the stacking direction, to the other second layer.

In the above configuration, the potential may be divided between the split layers.

In one aspect of the present invention, at least one of openings of the splitting hole is filled with an insulating material, and the third layer is arranged on the insulating material.

In the above configuration, the substrate may be miniaturized.

In one aspect of the present invention, a pad connecting a control semiconductor element and a power semiconductor element is formed on the third layer.

In the above configuration, the power substrate and the control substrate may be integrated.

In one aspect of the present invention, a pattern of at least one of the pair of first layers is connected to a housing.

The configuration described above has superior heat radiation property.

To achieve the above object, in a method for manufacturing a multi-layer wiring board according to the present invention, the patterned inner layer metal plate is arranged between the prepregs, and the outer layer metal foil that is thinner than the inner layer metal plate and has a current path with smaller cross-sectional area than that of the current path in the inner layer metal plate is arranged on an exposed surface of at least one of the prepregs in the forming step. In the heating and pressurizing step, the block formed in the forming step is heated and pressurized to integrate the block. In the patterning step, the outer layer metal foil in the block integrated in the heating and pressurizing step is patterned.

Thus, a large current may flow to the patterned inner layer metal plate, and the conductive pattern occupies a small area. Further, a current smaller than that for the inner layer metal plate may flow to the patterned outer layer metal foil. The planar area may be small since the outer layer metal foil is arranged on the surface of the insulative base material. Therefore, the flow of a large current and a smaller current smaller are allowed while suppressing increases in the planar area of the substrate.

One aspect of the present invention further comprises a step of splitting a conductive pattern formed by the inner layer metal plate by performing a punching process on a partial region of the block integrated in the heating and pressurizing step.

In the above configuration, the conductive pattern including the inner layer metal plate may be split by performing the punching process on a partial region of the block integrated in the heating and pressurizing step.

### Effect of the Invention

The present invention allows for the flow of a large current and a smaller current while suppressing an increase in the planar area of the substrate.

### BRIEF DESCRIPTION OF THE DRAWINGS

FIG. 1 is a cross-sectional view of an electronic device in a first embodiment.

FIG. 2A is a cross-sectional view illustrating a manufacturing step of the electronic device, and FIG. 2B is a cross-sectional view illustrating a manufacturing step of the electronic device.

FIG. 3A is a cross-sectional view illustrating a manufacturing step of the electronic device, and FIG. 3B is a cross-sectional view illustrating a manufacturing step of the electronic device.

FIG. 4A is a cross-sectional view illustrating a manufacturing step of the electronic device, and FIG. 4B is a cross-sectional view illustrating a manufacturing step of the electronic device.

FIG. 5A is a cross-sectional view illustrating a manufacturing step of the electronic device, and FIG. 5B is a cross-sectional view illustrating a manufacturing step of the electronic device.

FIG. 6A is a cross-sectional view illustrating a manufacturing step of the electronic device, and FIG. 6B is a cross-sectional view illustrating a manufacturing step of the electronic device.

FIG. 7 is a cross-sectional view of an electronic device in a second embodiment.

FIG. 8 is a cross-sectional view of an electronic device in another example.

FIG. 9 is a cross-sectional view of an electronic device in a further example.

### EMBODIMENTS OF THE INVENTION

### First Embodiment

A first embodiment of the present invention will now be described with reference to the drawings.

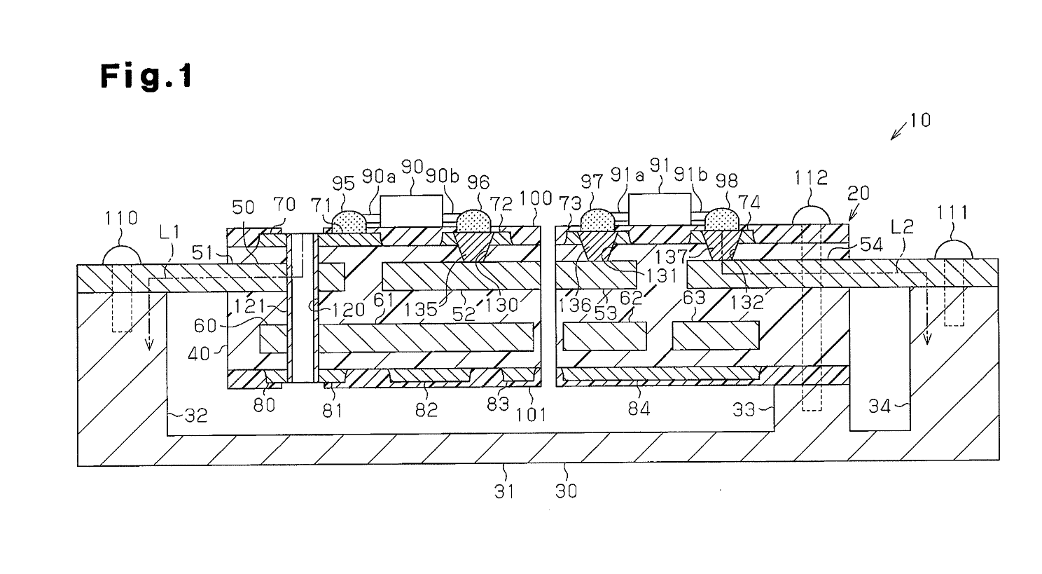

As shown in FIG. 1, an electronic device 10 includes a multi-layer wiring board 20 and an aluminum housing 30.

The multi-layer wiring board 20 includes an insulative base material 40, inner layer copper plates 50, 60 serving as inner layer metal plates arranged in the insulative base material 40, and outer layer copper foils 70, 80 serving as outer layer metal foils respectively arranged on the two surfaces (both front and back surfaces) of the insulative base material 40.

The insulative base material 40 is a planar and arranged horizontally. The inner layer copper plates 50, 60 are arranged spaced apart from each other in the vertical direction in the insulative base material 40. The inner layer copper plates 50, 60 are arranged so that the inner layer copper plate 50 is arranged at the upper layer side, and the inner layer copper plate 60 is arranged at the lower layer side. The thickness of the inner layer copper plates 50, 60 is, for example, approximately 100 to 200 μm.

The inner layer copper plate 50 is patterned in a punching process. That is, conductive patterns 51, 52, 53, 54 are formed in a punch pressing process, and the conductive patterns 51, 52, 53, 54 allow for the flow of a large current.

The inner layer copper plate 60 is patterned in a punching process. That is, conductive patterns 61, 62, 63 are formed in a punch pressing process, and the conductive patterns 61, 62, 63 allow for the flow of a large current. In this manner, the conductive pattern formed by the two inner layers (inner layer copper plates 50, 60) function as the wiring for a power supply system.

The conductive pattern 51 extends out of the insulative base material 40 from one end face of the insulative base material 40 in the horizontal direction. The conductive pattern 54 extends out of the insulative base material 40 from the other end face of the insulative base material 40 in the horizontal direction.

The thickness of the outer layer copper foils 70, 80 is, for example, approximately 18 to 35 μm. The outer layer copper foil 70 is arranged on an upper surface of the insulative base material 40 and patterned by undergoing wet etching. Specifically, a micro-fabrication process is performed to form conductive patterns 71, 72, 73, 74. The conductive patterns 71, 72, 73, 74 formed by the outer layer copper foil 70 function as a signal line. The outer layer copper foil 80 is arranged on a lower surface of the insulative base material 40 and patterned by undergoing wet etching. Specifically, a micro-fabrication process is performed to form conductive patterns 81, 82, 83, 84. The conductive patterns 81, 82, 83, 84 formed by the outer layer copper foil 80 function as a signal line.

In this manner, the wiring of a signal system includes the conductive patterns formed by the two outer layers (outer layer copper foils 70, 80).

In this case, the outer layer copper foils 70, 80 may be patterned in a punching process instead of an etching process. Further, the outer layer copper foils 70, 80 may be patterned through copper plating, printing, and the like.

The outer layer copper foils 70, 80 are thinner than the inner layer copper plates 50, 60 and form a current path having a smaller cross-sectional area than that of the current path formed by the inner layer copper plates 50, 60.

Via holes 130, 131, 132 are formed in portions between the outer layer copper foil 70 and the inner layer copper plate 50 in the insulative base material 40. Plated layers 135, 136, 137 are formed in the via hole 130. The conductive pattern 72 formed by the outer layer copper foil 70 is electrically connected to the conductive pattern 52 formed by the inner layer copper plate 50 by the plated layer 135 in the via hole 130. The conductive pattern 73 formed by the outer layer copper foil 70 is electrically connected to the conductive pattern 53 formed by the inner layer copper plate 50 with the plated layer 136 in the via hole 131. Further, the conductive pattern 74 formed by the outer layer copper foil 70 is electrically connected to the conductive pattern 54 formed by the inner layer copper plate 50 with the plated layer 137 in the via hole 132.

The multi-layer wiring board 20 includes a through hole 120. The through hole 120 electrically connects the inner layer copper plates 50, 60 and the outer layer copper foils 70, 80. Specifically, the conductive pattern 51 including the inner layer copper plate 50, the conductive pattern 61 including the inner layer copper plate 60, the conductive pattern 71 including the outer layer copper foil 70, and the conductive pattern 81 including the outer layer copper foil 80 are connected by a plated layer 121 of the through hole 120.

In this manner, the conductive patterns 51, 52, 53, 54, 61, 62, 63 that form current paths through which large current flows are formed by punching out the thick inner layer copper plates 50, 60. The conductive patterns 71, 72, 73, 74, 81, 82, 83, 84 that form signal paths are formed by etching the outer layer copper foils 70, 80 (fine patterns are formed). The conductive patterns 51, 52, 53, 54, 61, 62, 63 formed by the thick inner layer copper plates 50, 60 and the conductive patterns 71, 72, 73, 74, 81, 82, 83, 84, which are formed by performing a micro-fabricating process on the thin outer layer copper foils 70, 80, are integrated to configure the multi-layer wiring board 20.

Electronic components 90, 91 are mounted on an upper surface of the multi-layer wiring board 20. Specifically, a solder resist 100 is formed on the insulative base material 40 including the outer layer copper foil 70, and the electronic component 90 is arranged on the solder resist 100. The conductive pattern 71 formed by the outer layer copper foil 70 and a lead 90a of the electronic component 90 are joined by solder 95. The conductive pattern 72 formed by the outer layer copper foil 70 and a lead 90b of the electronic component 90 are joined by solder 96.

In the same manner, the electronic component 91 is arranged on the solder resist 100. The conductive pattern 73, formed by the outer layer copper foil 70, and a lead 91a of the electronic component 91 are joined by solder 97. The conductive pattern 74, formed by the outer layer copper foil 70, and a lead 91b of the electronic component 91 are joined by solder 98.

A solder resist 101 is formed on a lower surface of the insulative base material 40 including the outer layer copper foil 80.

The aluminum housing 30 includes a plate portion 31 and substrate supporting portions 32, 33, 34. The plate portion 31 is arranged in a horizontal direction, and the substrate supporting portions 32, 33, 34 project from the upper surface of the plate portion 31. The conductive pattern 51 including the inner layer copper plate 50 is arranged on the upper surface of the substrate supporting portion 32. The conductive pattern 54, formed by the inner layer copper plate 50, is arranged on the upper surface of the substrate supporting portion 34. Further, the lower surface of the multi-layer wiring board 20 is arranged on the upper surface of the substrate supporting portion 33.

A screw 110, which extends through the conductive pattern 51 formed by the inner layer copper plate 50, is fastened to the substrate supporting portion 32 of the aluminum housing 30. A screw 111, which extends through the conductive pattern 54 formed by the inner layer copper plate 50, is fastened to the substrate supporting portion 34 of the aluminum housing 30. This fastens and fixes the conductive patterns 51, 54, which are formed from the inner layer copper plate 50 and extend out of the insulative base material 40, to the aluminum housing 30. Thus, the multi-layer wiring board 20 may be easily fixed to the aluminum housing 30.

A screw 112, which extends through the multi-layer wiring board 20, is fastened to the substrate supporting portion 33 of the aluminum housing 30. Thus, the multi-layer wiring board 20 is supported while in contact with the upper surface of the substrate supporting portion 33 of the aluminum housing 30.

The conductive pattern 51 and the conductive pattern 54 formed from the inner layer copper plate 50 are, for example, body-grounded (set to ground potential of the power supply system).

The electronic components 90, 91 generate heat when driven. The heat is released to the aluminum housing 30 through the paths L1, L2 indicated by single-dashed lines in FIG. 1.

The operation of the electronic device 10 will now be described.

The electronic components 90, 91 generate heat when driven. The heat is released through the paths L1, L2 indicated by the single-dashed lines in FIG. 1. That is, as denoted by L1, the heat is released through a path of the electronic component 90→the plated layer 121 of the through hole 120→the conductive pattern 51 formed from the inner layer copper plate 50→the substrate supporting portion 32 of the aluminum housing 30. Further, as denoted by L2, the heat is released through a path of the electronic component 91→the plated layer 137 of the via hole 132→the conductive pattern 54 formed from the inner layer copper plate 50→the substrate supporting portion 34 of the aluminum housing 30.

A method for manufacturing the electronic device 10 will now be described.

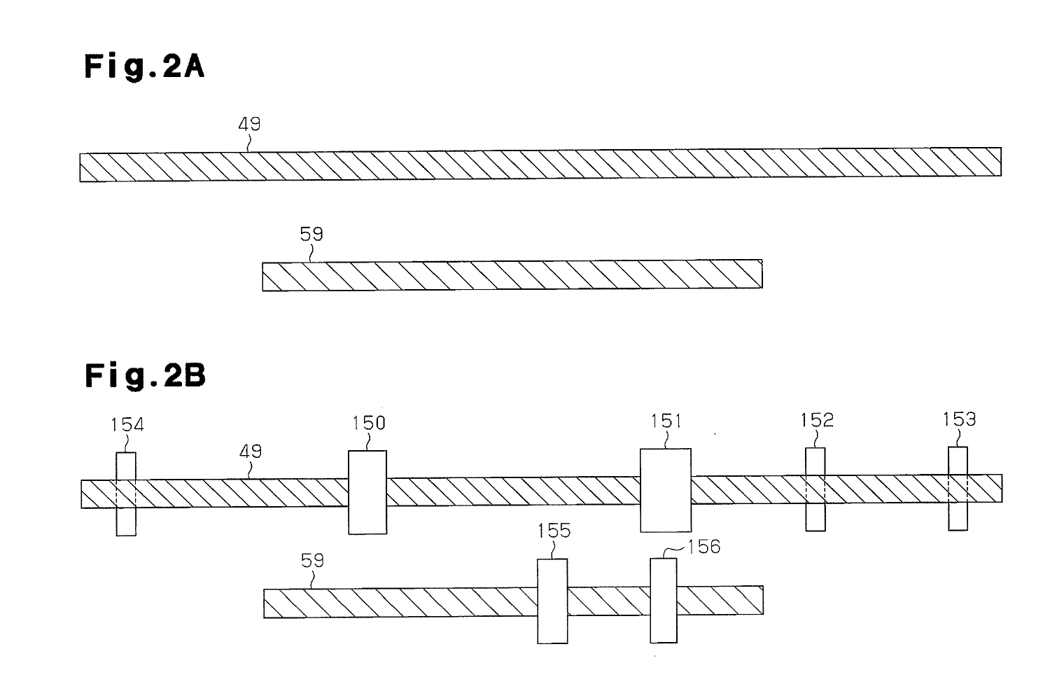

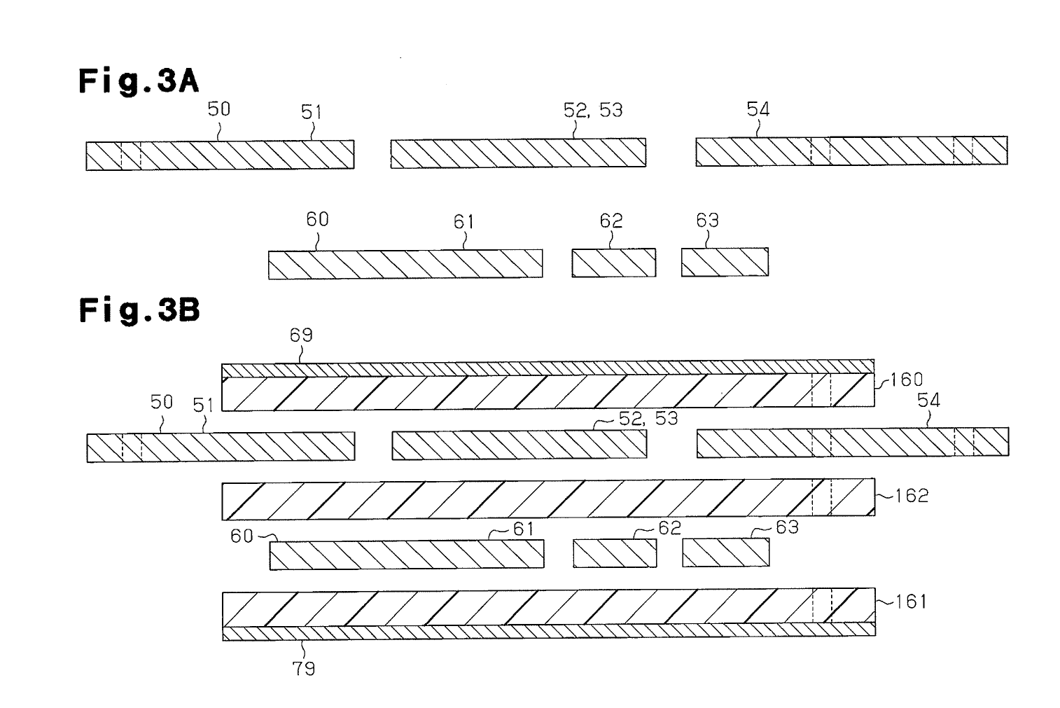

First, as shown in FIG. 2A, inner layer copper plates 49, 59 that have not undergone patterning are prepared. As shown in FIG. 2B, the inner layer copper plates 49, 59 are punched out by press dies 150, 151, 152, 153, 154, 155, 156. As shown in FIG. 3A, this forms the patterned inner layer copper plates 50, 60. Further, the locations punched by the press dies 152, 153, 154 of FIG. 2B form screw insertion holes through which the screws 110, 111, 112 of FIG. 1 are extended.

Subsequently, as shown in FIG. 3B, the patterned inner layer copper plates 50, 60, a prepreg 160, an outer layer copper foil 69 formed on the surface of the prepreg 160, a prepreg 161, an outer layer copper foil 79 formed on the surface of the prepreg 161, and a prepreg 162 are prepared. The outer layer copper foil 79 prior to patterning, the prepreg 161, the patterned inner layer copper plate 60, the prepreg 162, the patterned inner layer copper plate 50, the prepreg 160, and the outer layer copper foil 69 prior to patterning are stacked and arranged from the bottom. That is, the inner layer copper plates 50, 60 patterned in the punching process are arranged between the prepregs 160, 161, 162. The outer layer copper foils 69, 79 serving as the outer layer metal foils are arranged on the exposed surfaces of the prepregs 160, 161. This forms a block (stacked body).

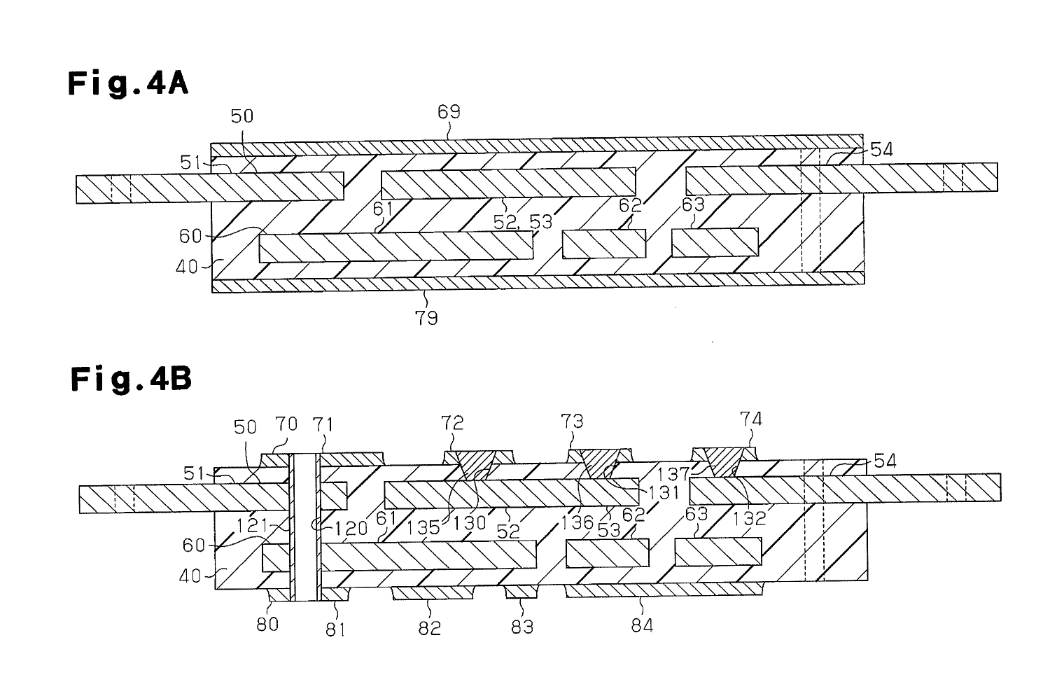

The formed block is heated and pressurized by a stacking press and integrated (resin is melted and cured) as shown in FIG. 4A. In this manner, by performing a full drying process, costs may be lowered.

Then, the outer layer copper foils 69, 79 in the integrated block (stacked body) are patterned by performing wet etching to form the conductive patterns 71, 72, 73, 74, 81, 82, 83, 84, as shown in FIG. 4B.

Further, connection of the two surfaces and the layers is performed. Specifically, the through hole 120 is formed to electrically connect the conductive patterns 71, 51, 61, 81 with the plated layer 121, and the via holes 130, 131, 132 are formed to electrically connect the conductive patterns 72, 52, the conductive patterns 73, 53, and the conductive patterns 74, 54 with the plated layers 135, 136, 137.

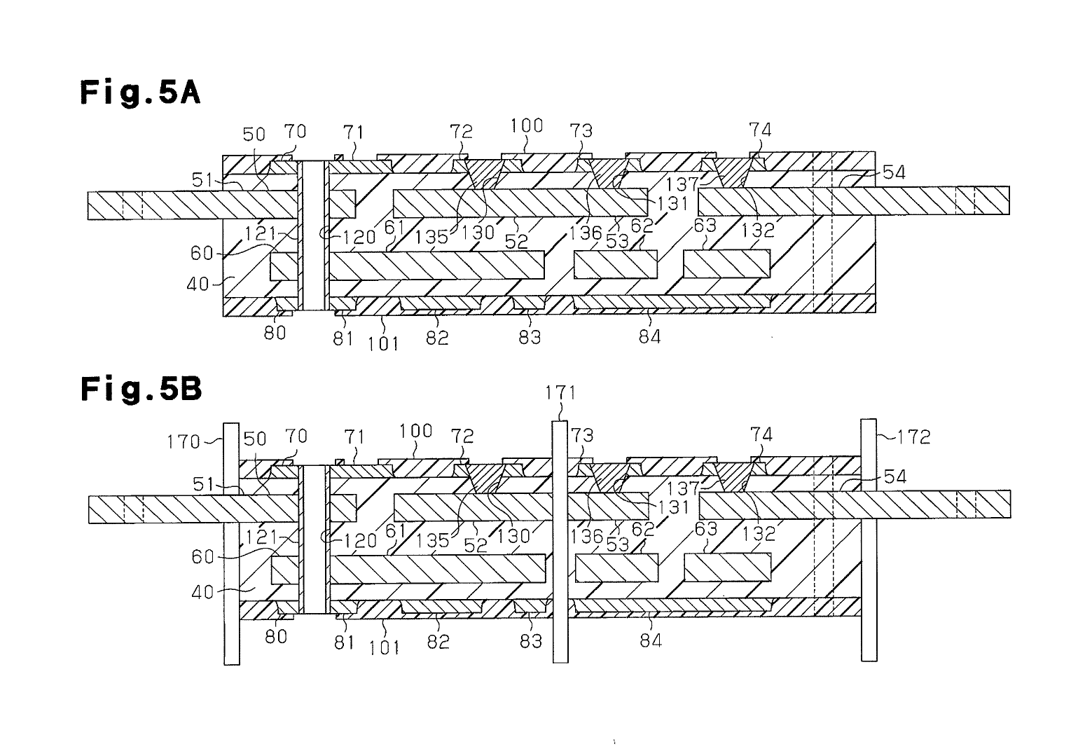

Then, as shown in FIG. 5A, the solder resists 100, 101 are formed.

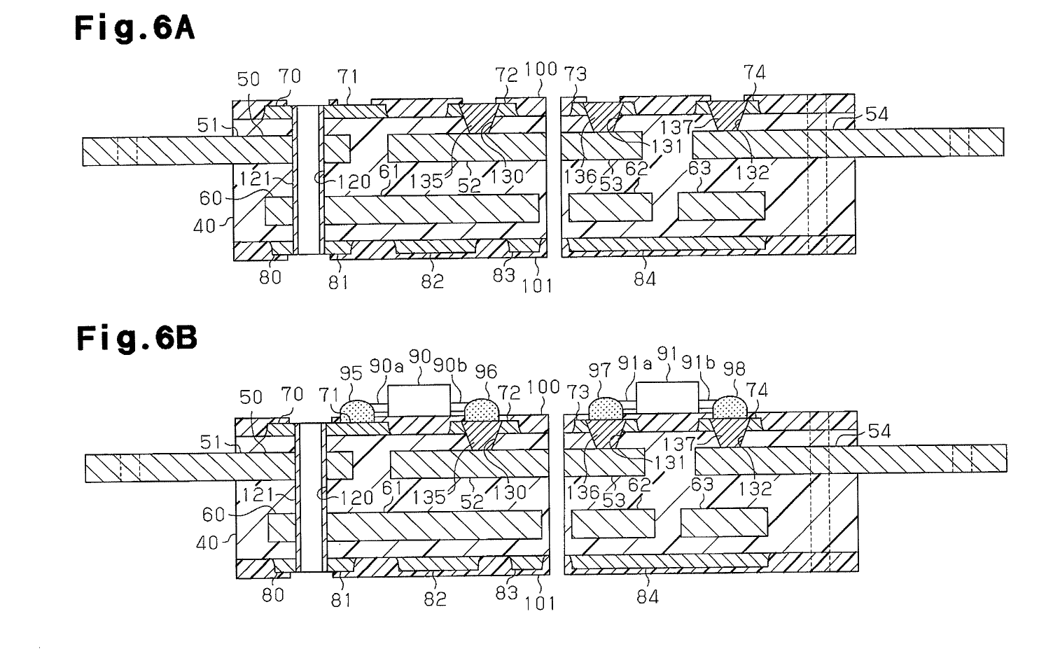

Next, as shown in FIG. 5B, outer shape formation and splitting of the inner layer pattern are performed. That is, cutting for the formation of the outer shape, and cutting of the connected portion of the conductive patterns 52, 53 in the inner layer copper plate 50 are carried out by performing a punching process with the press dies 170, 171, and 172. In other words, the conductive pattern 52 and the conductive pattern 53 are split by the insertion of the press die 171. The result is as shown in FIG. 6A.

As shown in FIG. 6B, the electronic components 90, 91 are then placed on the solder resist 100 and connected with the solders 95, 96, 97, 98.

Subsequently, as shown in FIG. 1, the conductive patterns 51, 54 formed from the inner layer copper plate 50 are placed on the upper surfaces of the substrate supporting portions 32, 34 of the aluminum housing 30 and the multi-layer wiring board 20 is placed on the upper surface of the substrate supporting portion 33 of the aluminum housing 30. The screws 110, 111, which are extended through the conductive patterns 51, 54 formed from the inner layer copper plate 50, are fastened to the substrate supporting portions 32, 34 of the aluminum housing 30, and the screw 112 extending through the multi-layer wiring board 20 is fastened to the substrate supporting portion 33 of the aluminum housing 30. This couples the multi-layer wiring board 20 with the electronic components 90, 91 to the aluminum housing 30.

Consequently, the electronic device 10 shown in FIG. 1 may be manufactured.

The embodiment described above has the following advantages.

(1) The multi-layer wiring board 20 includes the insulative base material 40 and the inner layer copper plates 50, 60, which are arranged and patterned in the insulative base material 40. The inner layer copper plates 50, 60 are patterned in a punching process. Further, the multi-layer wiring board 20 includes the outer layer copper foils 70, 80, which are arranged on the surface of the insulative base material 40 in a patterned state, thinner than the inner layer copper plates 50, 60, and have a smaller current path cross-sectional area than the inner layer copper plates 50, 60. The outer layer copper foils 70, 80 are etched and patterned.

Thus, the patterned inner layer copper plats 50, 60 are arranged in the insulative base material 40, and a large current is allowed to flow to the patterned inner layer copper plates 50, 60. Further, the patterned outer layer copper foils 70, 80 are arranged on the surface of the insulative base material 40, and a smaller current than that for the inner layer copper plates 50, 60 is allowed to flow to the outer layer copper foils 70, 80. When a large current flows through the conductive pattern, for a thin conductive pattern, the width needs to be increased since a large cross-sectional area is necessary and a wide area occupied by the conductive pattern becomes necessary. In the present embodiment, a large current is allowed to flow to the patterned inner layer copper plates 50, 60. Thus, the area occupied by the conductive pattern is small. Furthermore, a current smaller than that for the inner layer copper plates 50, 60 flows to the patterned outer layer copper foils 70, 80, and the outer layer copper foils 70, 80 are arranged on the surface of the insulative base material 40. Thus, the planar area is small. The inner layer copper plates 50, 60 are patterned in a punching process and thus do not require etching for patterning.

The patterned outer layer copper foils 70, 80 are arranged on the surface of the insulative base material 40, and the outer layer copper foils 70, 80 are etched to form fine patterns.

As a result, a large current and a smaller current are allowed to flow while suppressing an increase in the planar area of the substrate. Further, fine patterns (microscopic pattern) are also easily formed.

(2) The conductive patterns 51, 54, formed from the inner layer copper plate 50, extend out of the insulative base material 40 and are fixed to the aluminum housing 30 by the screws 110, 111. This uses (obtains) the conductive patterns 51, 54 formed from the inner layer copper plate 50 as heat releasing paths that release (radiate) the heat generated by the electronic components 90, 91 through the conductive patterns 51, 54 and cool the electronic components 90, 91.

(3) The multi-layer wiring board 20 is fastened to the aluminum housing 30 with the screw 112. This obviates the lifting of the multi-layer wiring board 20 at the substrate supporting portion 33 of the aluminum housing 30 when the conductive patterns 51, 54, formed from the inner layer copper plate 50, are extended outside.

(4) The thick pattern is formed by performing a press punching process on the inner layer copper plates 50, 60 and not formed by performing etching. This reduces costs. In detail, the thick inner layer pattern is formed by performing a press punching process (direct press) on the inner layer copper plates 50, 60 so that the inner layers undergo full drying. This reduces costs.

(5) The conductive patterns of the inner layer and the conductive patterns of the outer layer are connected with the through hole 120 and the via holes 130, 131, 132 (connected with the plating).

(6) A method for manufacturing the multi-layer wiring board 20 includes a forming step, a heating and pressurizing step, and a patterning step. In the forming step, the patterned inner layer copper plates 50, 60 are arranged between the prepregs 160, 161, 162. The outer layer copper foils 69, 79, which are thinner than the inner layer copper plates 50, 60 and have a smaller current path cross-sectional area than the inner layer copper plates 50, 60, are arranged on the exposed surfaces of the prepregs 160, 161. In broad terms, the outer layer copper foil is arranged on the surface of at least one of the prepregs in which the surface is exposed. The patterning of the inner layer copper plates 50, 60 is performed by the punching process. In the heating and pressurizing step, the block formed in the forming step is heated and pressurized to be integrated. In the patterning step, the outer layer copper foils 69, 79 in the block integrated in the heating and pressurizing step are patterned. The outer layer copper foils 69, 79 are etched and patterned.

Thus, a large current is allowed to flow to the patterned inner layer copper plates 50, 60, and a small area is occupied by the conductive pattern. Further, a punching process is performed to form the patterns. This eliminates the need to perform etching. Fine patterns are formed by the etching of the outer layer copper foils 69, 79. In this manner, a large current and a smaller current are allowed to flow while suppressing an increase in the planar area of the substrate. Further, fine patterns are easily formed.

(7) A further step splits the conductive patterns 52, 53 formed by the inner layer copper plate 50 by performing a punching process on a partial region of the block integrated in the heating and pressurizing step. This allows for the conductive patterns 52, 53 to be split in a positioned state and arranged at desired positions.

### Second Embodiment

A second embodiment will now be described focusing on differences from the first embodiment.

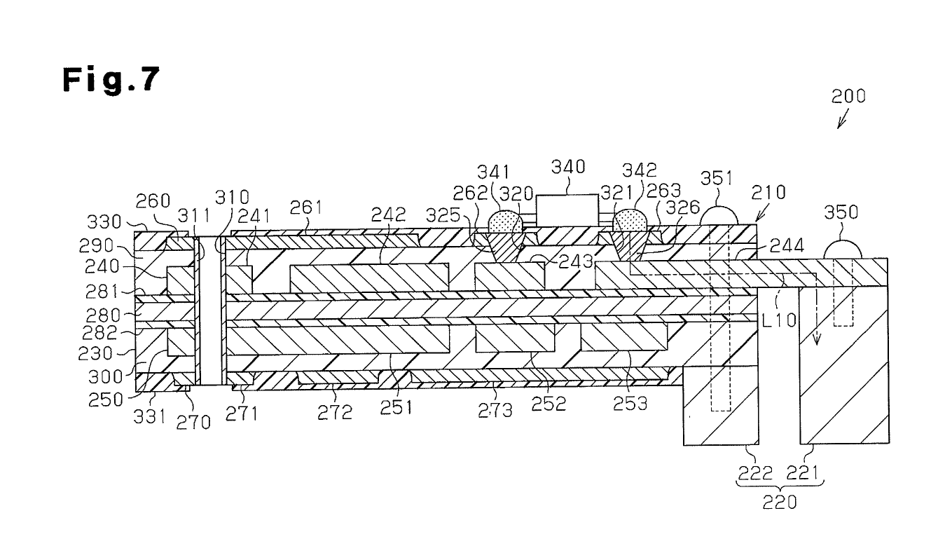

The present embodiment has the configuration shown in FIG. 7 instead of that shown in FIG. 1. In FIG. 7, an electronic device 200 includes a multi-layer wiring board 210 and an aluminum housing 220. The multi-layer wiring board 210 includes an insulative base material 230, inner layer copper plates 240, 250 serving as inner layer metal plates, and outer layer copper foils 260, 270 serving as outer layer metal foils. The insulative base material 230 includes an insulative core substrate 280, and the patterned inner layer copper plates 240, 250 are adhered to the insulative core substrate 280.

The thickness of the insulative core substrate 280 is, for example, about 400 μm. The thickness of the outer layer copper foils 260, 270 for a small current is, for example, approximately 18 to 35 μm. The thickness of the inner layer copper plates 240, 250 for a large current is, for example, approximately 100 to 200 μm.

The inner layer copper plate 240 is adhered to the upper surface of the insulative core substrate 280 with an adhesive sheet 281, and the inner layer copper plate 250 is adhered to the lower surface of the insulative core substrate 280 with an adhesive sheet 282. The thickness of the adhesive sheets 281, 282 is, for example, approximately 40 μm.

The inner layer copper plate 240 undergoes a punching process and is patterned to a desired shape to form conductive patterns 241, 242, 243, 244. The inner layer copper plate 250 also undergoes a punching process and is patterned to a desired shape to form conductive patterns 251, 252, 253.

An insulating layer 290 is arranged on the upper surface of the insulative core substrate 280 including the inner layer copper plate 240. An insulating layer 300 is arranged on the lower surface of the insulative core substrate 280 including the inner layer copper plate 250. The inner layer copper plates 240, 250 are thus arranged in the insulative base material 230 and patterned in a punching process.

The outer layer copper foil 260 is arranged on the upper surface of the insulative base material 230 (insulating layer 290). The outer layer copper foil 270 is arranged on the lower surface of the insulative base material 230 (insulating layer 300). The outer layer copper foil 260 is etched and patterned to a desired shape to form conductive patterns 261, 262, 263. The outer layer copper foil 270 is also etched and patterned to a desired shape to form conductive patterns 271, 272, 273. Thus, the outer layer copper foils 260, 270 arranged on the surface of the insulative base material 230 are etched and patterned. In this case, the outer layer copper foils 260, 270 may be patterned in a punching process instead of etching, and the outer layer copper foils 260, 270 may be patterned by performing copper plating, printing, or the like. The outer layer copper foils 260, 270 are thinner than the inner layer copper plates 240, 250 and have a current path with a smaller cross-sectional area than the current path of the inner layer copper plates 240, 250.

The conductive patterns 261, 241, 251, 271 are electrically connected by a plated layer 311 of a through hole 310. Further, the conductive pattern 243 and the conductive pattern 262, and the conductive pattern 244 and the conductive pattern 263 are electrically connected by plated layers 325, 326 of the via holes 320, 321.

A solder resist 330 is formed on the upper surface of the insulative base material 230 (insulating layer 290) including the outer layer copper foil 260. A solder resist 331 is formed on the lower surface of the insulative base material 230 (insulating layer 300) including the outer layer copper foil 270. An electronic component 340 is placed on the solder resist 330 connected by solders 341, 342.

The conductive pattern 244 formed from the inner layer copper plate 240 extends out of the side surface of the insulative base material 230 (insulative core substrate 280) in the horizontal direction and is fixed to the substrate supporting portion 221 of the aluminum housing 220 with a screw 350. A screw 351 extending through the multi-layer wiring board 210 is fastened to the substrate supporting portion 222 of the aluminum housing 220, and the multi-layer wiring board 210 is supported while in contact with the upper surface of the substrate supporting portion 222 of the aluminum housing 220.

The electronic component 340 generates heat when driven, and the heat is released (radiated) to the substrate supporting portion 221 of the aluminum housing 220 through the plated layer 326 of the via hole 321 and the conductive pattern 244 formed from the inner layer copper plate 240, as denoted by L10.

In a manufacturing method, the patterned inner layer copper plate 240 is adhered to the upper surface of the insulative core substrate 280 with the adhesive sheet 281, and the patterned inner layer copper plate 250 is adhered to the lower surface of the insulative core substrate 280 with the adhesive sheet 282. A punching process is performed to pattern the inner layer copper plates 240, 250. The patterned inner layer copper plates 240, 250 are held between prepregs (prepregs that become the insulating layers 290, 300), and the outer layer copper foils, prior to patterning, are arranged on the exposed surface of the prepregs (prepregs to become the insulating layers 290, 300) (forming step).

Furthermore, the formed block is pressurized and heated to be integrated (heating and pressurizing step). The outer layer copper foil in the integrated block is then patterned (patterning step). The outer layer copper foil is patterned and etched.

The connection of the two surfaces and the layers is then performed. Specifically, the through hole 310 is formed to electrically connect the conductive patterns 261, 241, 251, 271 by the plated layer 311, and the via holes 320, 321 are formed to electrically connect the conductive patterns 243, 262 and the conductive patterns 244, 263 by the plated layers 325, 326.

Furthermore, the solder resists 330, 331 are formed and the outer shape formation is carried out (perform cutting for formation of the outer shape). The electronic component 340 is then connected with the solders 341, 342. Subsequently, the conductive pattern 244 formed from the inner layer copper plate 240 is placed on the upper surface of the substrate supporting portion 221 of the aluminum housing 220, and the multi-layer wiring board 210 is placed on the upper surface of the substrate supporting portion 222 of the aluminum housing 220. The screw 350, which extends through the conductive pattern 244 formed by the inner layer copper plate 240, is then fastened to the substrate supporting portion 221 of the aluminum housing 220, and the screw 351, which extends through the multi-layer wiring board 210, is fastened to the substrate supporting portion 222 of the aluminum housing 220. This couples the multi-layer wiring board 210 including the electronic component 340 to the aluminum housing 220.

Consequently, the electronic device 200 shown in FIG. 7 may be manufactured.

The present embodiment may also include a step of splitting the conductive pattern formed from the inner layer copper plate by performing the punching process on a partial region of the block integrated in the heating and pressurizing step as described in (7) of the first embodiment.

The embodiments are not limited to the foregoing description and may have the following forms.

In FIGS. 1 and 7, the copper foil (pattern) is arranged on each of two surfaces of the insulative base material, which is a double-sided substrate but may be arranged on only one surface of the insulative base material, which may be a one-sided substrate.

In FIG. 1, two inner layer copper plates are used. Instead, one inner layer copper plate may be arranged between the two insulating layers (two prepregs) so that there is only one layer. Furthermore, three or more layers of inner layer copper plates may be used.

In the same manner, in FIG. 7, two inner layer copper plates are used. Instead, only one inner layer copper plate may be adhered to only one surface of the insulative core substrate 280 so that there is only one layer. Further, three or more inner layer copper plates may be arranged.

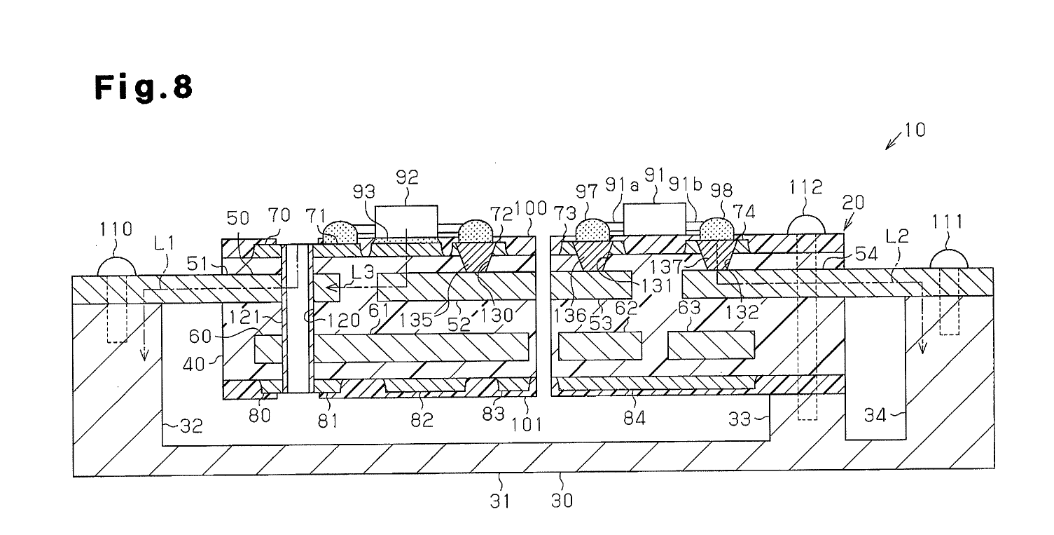

Referring to FIG. 8, as denoted by L3, a path for heat may be formed from the back surface electrode of the lower surface of the electronic component 92 through the solder 93→inner layer copper plate 50→aluminum housing 30. That is, the heat generated by the electronic component 92 may be transferred through the solder 93 serving as a joining material and released to the aluminum housing 30 through the inner layer copper plate 50. In this case, heat is released through the back surface electrode of the electronic component 92 so that the heat radiation area can be increased thus realizing a superior heat radiation property.

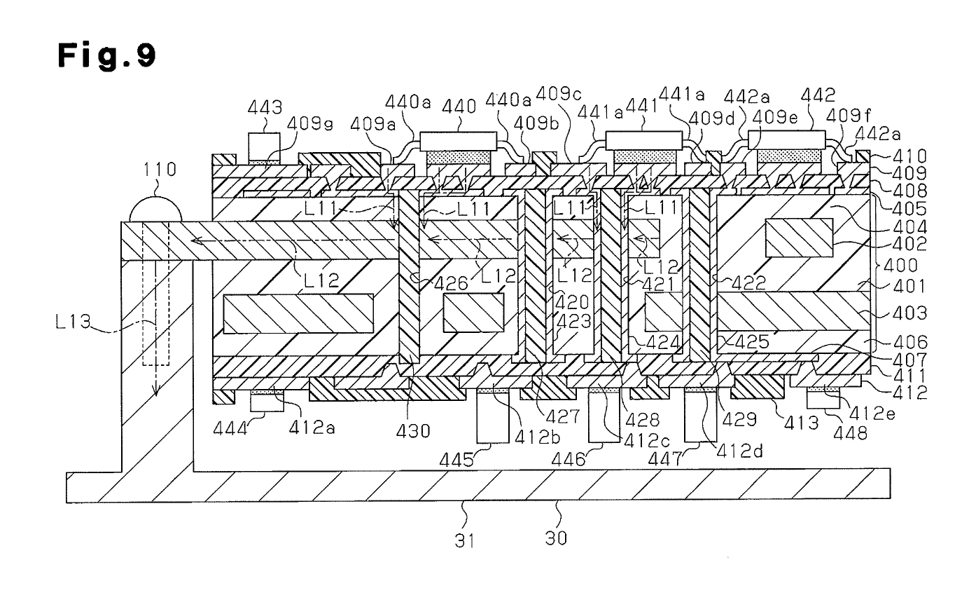

As shown in FIG. 9, a six-layer structure of a pair of first layers 402, 403 formed by the inner layer metal plate and arranged one above the other in a stacking direction, a pair of second layers 405, 407 formed by the outer layer metal foil and arranged one above the other in the stacking direction, and a pair of third layers 409, 412 arranged one above the other in the stacking direction may be employed. The third layers 409, 412 may be metal plates for large current or metal foils for small current. In FIG. 9, the first layers 402, 403 are inner layer metal plates arranged and patterned inside the insulative base material 400, the second layers 405, 407 are outer layer metal foils arranged in a patterned state on the surface of the insulative base material 400, and having a thinner thickness than the inner layer metal plates and a smaller cross-sectional area of the current path than the cross-sectional area of the current path in the inner layer metal plate. The first layer 402 is formed on one surface of an insulating layer 401, which is the core material, and the first layer 403 is formed on the other surface of the insulating layer 401. The second layer 405 is formed on the first layer 402 through an insulating layer 404, and the second layer 407 is formed on the first layer 403 through an insulating layer 406. The third layer 409 is formed on the second layer 405 through an insulating layer 408, and the third layer 409 is covered with an insulating film 410. The third layer 412 is formed on the second layer 407 through an insulating layer 411, and the third layer 412 is covered with an insulating film 413.

The through holes 420, 421, 422 are formed over the pair of second layers 405, 407. The through holes 420, 421, 422 include plated layers 423, 424, 425. The through holes 420, 421, 422 are filled with resins 427, 428, 429, and the third layers 409, 412 are arranged thereon. In broad terms, at least one opening of the through holes 420, 421, 422 is filled with the resin 427, 428, 429 serving as an insulating material, and the third layers 409, 412 are arranged thereon. This allows for the substrate to be miniaturized.

Each of the pair of second layers 405, 407 is split by a splitting hole 426 extending in the stacking direction. In other words, the splitting hole 426 extending in the stacking direction from one of the pair of second layers 405, 407 to the other second layer splits each of the pair of first layers 402, 403, and splits each of the pair of second layers 405, 407. Thus, the substrate is split, and the potential can be divided between the split layers. The splitting hole 426, which is the split area, is filled with resin 430, and the third layers 409, 412 are arranged thereon. In broad terms, at least one opening of the splitting hole 426 is filled with the resin 430 serving as the insulating material, and the third layers 409, 412 are arranged thereon. This allows for the substrate to be miniaturized.

The third layer 409 includes pads 409a, 409b, 409c, 409d, 409e, 409f, 409g that connect the power semiconductor elements 440, 441, 442 and the control semiconductor element 443. The third layer 412 includes pads 412a, 412b, 412c, 412d, 412e connected to the control semiconductor elements 444, 445, 446, 447, 448. In broad terms, the third layers 409, 412 include pads that connect the control semiconductor elements and the power semiconductor elements. The leads 440a of the power semiconductor element 440 of FIG. 9 are joined with the pads 409a, 409b, the leads 441a of the power semiconductor element 441 are joined with the pads 409c, 409d, and the leads 442a of the power semiconductor element 442 are joined with the pads 409e, 409f. The back surface electrode of the control semiconductor element 443 is joined with the pad 409g. The back surface electrodes of the control semiconductor elements 444, 445, 446, 447, 448 are joined with the pads 412a, 412b, 412c, 412d, 412e. In this manner, the power substrate and the control substrate may be integrated.

The pattern of the first layer 402 is connected to the housing 30. In broad terms, the pattern of at least one of the pair of first layers 402, 403 is connected to the housing 30. The heat generated by the power semiconductor elements 440, 441, 442 of FIG. 9 is released through the paths denoted by L11, L12, L13, and reaches the housing 30 from the first layer 402 through the through holes 420, 421, 422, etc. This realizes a superior heat radiation property. Furthermore, heat may be radiated through the through holes 420, 421, 422.

The metal plate and the metal foil are made of copper but may be made of other metals, for example, aluminum.

### DESCRIPTION OF REFERENCE CHARACTERS

20: multi-layer wiring board, 30: aluminum housing, 40: insulative base material, 50: inner layer copper plate, 60: inner layer copper plate, 69: outer layer copper foil, 70: outer layer copper foil, 79: outer layer copper foil, 80: outer layer copper foil, 160: prepreg, 161: prepreg, 162: prepreg, 210: multi-layer wiring board, 220: aluminum housing, 230: insulative base material, 240: inner layer copper plate, 250: inner layer copper plate, 260: outer layer copper foil, 270: outer layer copper foil, 280: insulative core substrate, 400: insulative base material, 402: first layer, 403: first layer, 405: second layer, 407: second layer, 409: third layer, 409a: pad, 409b: pad, 409c: pad, 409d: pad, 409e: pad, 409f: pad, 409g: pad, 412: third layer, 412a: pad, 412b: pad, 412c: pad, 412d: pad, 412e: pad, 420: through hole, 421: through hole, 422: through hole, 426: splitting hole, 427: resin, 428: resin, 429: resin, 430: resin, 440: power semiconductor element, 441: power semiconductor element, 442: power semiconductor element, 443: control semiconductor element, 444: control semiconductor element, 445: control semiconductor element, 446: control semiconductor element, 447: control semiconductor element, 448: control semiconductor element.

1-14. (canceled)

15. A multi-layer wiring board comprising:
an insulative base material;
a pair of first layers arranged in the insulative base material and arranged one above the other in a stacking direction, wherein each of the first layers is formed from a patterned inner layer metal plate;
a pair of second layers arranged one above the other in the stacking direction, wherein each of the second layers is formed from an outer layer metal foil arranged in a patterned state on a surface of the insulative base material, wherein the outer layer metal foil is thinner than the inner layer metal plate and has a current path with a cross-sectional area smaller than that of a current path of the inner layer metal plate; and
a pair of third layers arranged one above the other in the stacking direction, wherein
a pad connected with a control semiconductor element and a pad connected with a power semiconductor element are formed in the third layer, and
the pad connected with the power semiconductor element is connected with the inner layer metal plate, and the pad connected with the control semiconductor element is connected with the outer layer metal foil.

16. The multi-layer wiring board according to claim 15, wherein a conductive pattern formed from the inner layer metal plate is extended out of the insulative base material and fixed to a housing.

17. The multi-layer wiring board according to claim 15, wherein the insulative base material includes an insulative core substrate, and the patterned inner layer metal plate is adhered to the insulative core substrate.

18. The multi-layer wiring board according to claim 15, wherein the inner layer metal plate is a copper plate.

19. The multi-layer wiring board according to claim 15, comprising a through hole extending in the stacking direction from one of the pair of second layers, arranged one above the other in the stacking direction, to the other second layer.

20. The multi-layer wiring board according to claim 19, wherein at least one of openings of the through hole is filled with an insulating material, and the third layer is arranged on the insulating material.

21. The multi-layer wiring board according to claim 15, further comprising a splitting hole extending in the stacking direction from one of the pair of second layers, arranged one above the other in the stacking direction, to the other second layer.

22. The multi-layer wiring board according to claim 21, wherein at least one of openings of the splitting hole is filled with an insulating material, and the third layer is arranged on the insulating material.

23. The multi-layer wiring board according to claim 15, wherein a pattern of at least one of the pair of first layers is connected to a housing.
